(19) United States
(12) Patent Application Publication
(10) Pub. No.: US 2025/0311496 A1
(43) Pub. Date: Oct. 2, 2025

(54) LIGHT-EMITTING ARRAY MODULE

(71) Applicant: Industrial Technology Research Institute, Hsinchu (TW)

(72) Inventors: Kung-Ching Chu, Taipei City (TW); Wei-Chung Chen, Hsinchu County (TW); Chia-Ping Lin, Hsinchu City (TW); Hung Tsou, Hsinchu County (TW); Chen-Wei Lin, Hsinchu City (TW); Ruo-Lan Chang, New Taipei City (TW)

(73) Assignee: Industrial Technology Research Institute, Hsinchu (TW)

(21) Appl. No.: 18/747,478

(22) Filed: Jun. 19, 2024

(30) Foreign Application Priority Data
Apr. 1, 2024 (TW) 113112355

(51) Int. Cl. H01L 27/15; H01L 33/58; H01L 33/60

(52) U.S. Cl. CPC H10H 29/142; H10H 20/855; H10H 20/856

(57) ABSTRACT

A light-emitting array module includes a light source array and microlens units disposed on the light source array. The light source array includes light-emitting elements arranged in an array. Each microlens unit includes a microlens, a stray light guiding layer, and a stray light reflecting layer. The stray light guiding layer is disposed at a side surface of the microlens. A refractive index of a medium or space at an outer side of the stray light guiding layer is less than a refractive index of the stray light guiding layer. The stray light reflecting layer is disposed at a side of the stray light guiding layer adjacent to the light source array. Light emitted by the light-emitting elements corresponding to the microlens units and reflected into the stray light guiding layer by the stray light reflecting layer undergoes total internal reflection on a surface of the stray light guiding layer.

### CROSS-REFERENCE TO RELATED APPLICATION

This application claims the priority benefit of Taiwan Application No. 113112355, filed on Apr. 1, 2024. The entirety of the above-mentioned patent application is hereby incorporated by reference herein.

### TECHNICAL FIELD

The disclosure relates to a light-emitting array module.

### BACKGROUND

With the development of display technology, the functions of displays have surpassed the rendering of flat images, encompassing the presentation of three-dimensional (3D) images and integral images. One method to display 3D or integral images involves arranging a microlens array in front of a light source array, with the microlens array facilitating the formation of the 3D or integral images.

However, when the light from the light source array passes through areas of the microlens array that do not correspond to specific microlenses, stray light may occur. This stray light can impact the clarity and sharpness of the images, leading to blurred edges, reduced image quality, and unintended color mixing in the 3D image patterns.

### SUMMARY

One of the exemplary embodiments provides a light-emitting array module that includes a light source array and a plurality of microlens units. The light source array includes a plurality of light-emitting elements arranged in an array. The microlens units are disposed on the light source array. Each of the microlens units includes a microlens, a stray light guiding layer, and a stray light reflecting layer. The stray light guiding layer is disposed on a side surface of the microlens, where a refractive index of a medium or space on an outer side of the stray light guiding layer is less than a refractive index of the stray light guiding layer. The stray light reflecting layer is disposed at one side of the stray light guiding layer adjacent to the light source array, where light emitted by the light-emitting elements corresponding to the microlens units and reflected into the stray light guiding layer by the stray light reflecting layer undergoes total internal reflection on a surface of the stray light guiding layer.

### BRIEF DESCRIPTION OF THE DRAWINGS

The accompanying drawings are included to provide a further understanding of the disclosure, and the accompanying drawings are incorporated in and constitute a part of this specification. The drawings illustrate the exemplary embodiments of the disclosure, and together with the description, serve to explain the principle of the disclosure.

FIG. 1A is a schematic partial cross-sectional view of a light-emitting array module including a microlens unit according to an embodiment of the disclosure.

FIG. 1B is a schematic top view of the light-emitting array module in FIG. 1A.

FIG. 2 is a schematic partial cross-sectional view of a light-emitting array module including a microlens unit according to another embodiment of the disclosure.

FIG. 3 is a schematic partial cross-sectional view of a light-emitting array module including a microlens unit according to yet another embodiment of the disclosure.

FIG. 4 is a schematic partial cross-sectional view of a light-emitting array module including a microlens unit and a portion of surrounding microlens units according to still another embodiment of the disclosure.

### DETAILED DESCRIPTION OF DISCLOSURED EMBODIMENTS

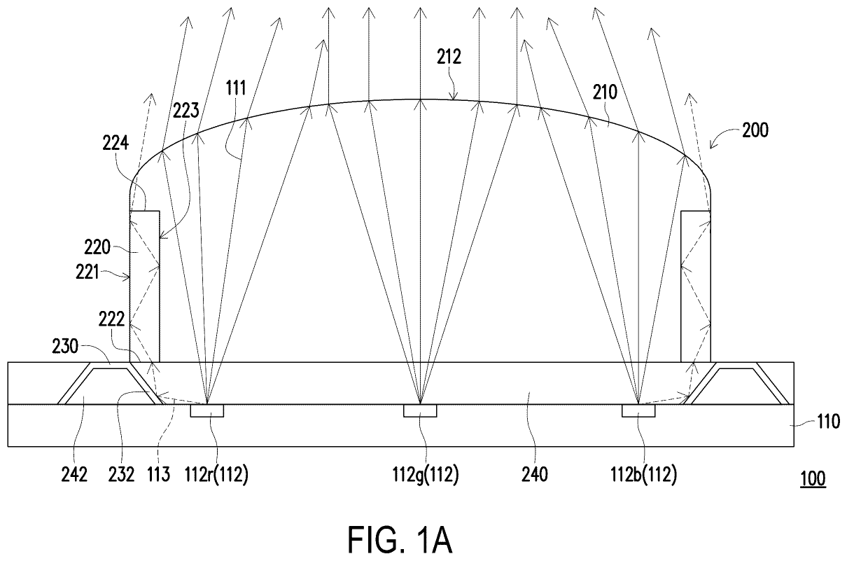

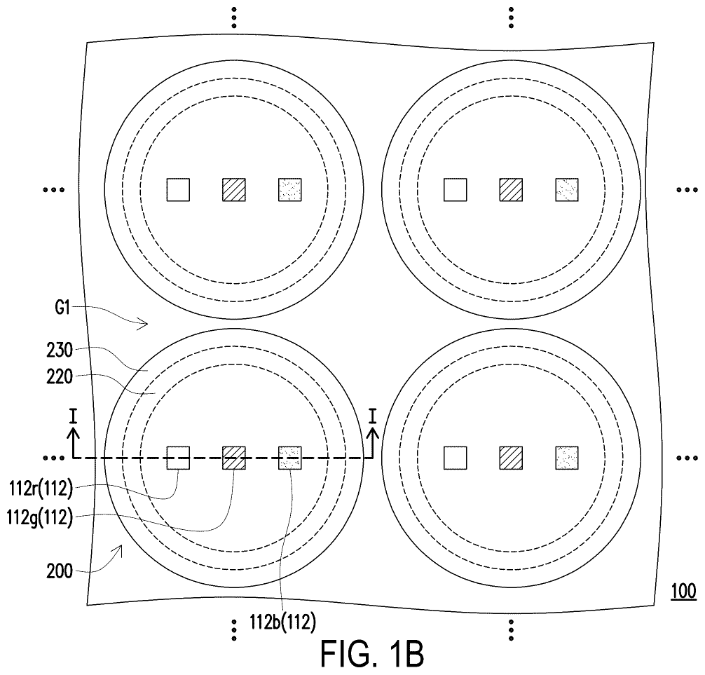

FIG. 1A is a schematic partial cross-sectional view of a light-emitting array module covering a microlens unit according to an embodiment of the disclosure. FIG. 1B is a schematic top view of the light-emitting array module in FIG. 1A. Here, FIG. 1A is a schematic cross-sectional view of the light-emitting array module in FIG. 1B along a line I-I. With reference to FIG. 1A and FIG. 1B, a light-emitting array module 100 provided in this embodiment includes a light source array 110 and a plurality of microlens units 200. The light source array 110 includes a plurality of light-emitting elements 112 arranged in an array, and the microlens units 200 are disposed on the light source array 110. In this embodiment, the light source array 110 is, for instance, a liquid crystal display (LCD) panel, an organic light-emitting diode (OLED) display panel, a millimeter light-emitting diode (mini-LED) display panel, a micro-LED display panel, a quantum dot organic light-emitting diode (QLED or QDLED) display panel, or the like, and each light-emitting element 112 is, for instance, a pixel or a sub-pixel of a display panel. In an embodiment, each light-emitting element 112 corresponding to the microlens unit 200 may include a red light-emitting element 112r, a green light-emitting element 112g, and a blue light-emitting element 112b. However, in other embodiments, each light-emitting element 112 corresponding to the microlens unit 200 may also include a light-emitting element of one single color or multiple colors.

Each microlens unit 200 may include a microlens 210, a stray light guiding layer 220, and a stray light reflecting layer 230. The stray light guiding layer 220 is disposed on a side surface of the microlens 210, where a refractive index of a medium (e.g., air, liquid pervious to light, a solid material pervious to light, and so on) or space (e.g., vacuum) on an outer side of the stray light guiding layer 220 is less than a refractive index of the stray light guiding layer 220. The stray light reflecting layer 230 is disposed on one side 222 of the stray light guiding layer 220 close to the light source array 110. Light 113 emitted by the light-emitting elements 112 corresponding to the microlens units 200 and reflected into the stray light guiding layer 220 by the stray light reflecting layer 230 undergoes total internal reflection on a surface 221 of the stray light guiding layer 220. In the present embodiment, light emitted by the light-emitting elements 112 includes light 111 and the light 113 emitted at a large viewing angle. Without the appropriate guidance from the stray light reflecting layer 230 and the stray light guiding layer 220 in this embodiment, the light 113 emitted at the large viewing angle is likely to become stray light because the light 113 cannot be transmitted to a refractive surface 212 of the microlens 210. In the present embodiment, the light 113 emitted at the large viewing angle may be reflected into the stray light guiding layer 220 by the stray light reflecting layer 230, e.g., entering the stray light guiding layer 220 from one side 222 of the stray light guiding layer 220. Since the refractive index of the stray light guiding layer 220 is greater than the refractive index of the medium or space on the outer side of the stray light guiding layer 220, when the light 113 is incident on the surface 221 of the stray light guiding layer 220 at an incident angle greater than the critical angle, the light 113 undergoes total internal reflection, thereby confining the light 113 to the microlens units 200. As such, the light 113 can be transmitted to the refractive surface 212 of the microlens 210 and becomes effective light. Accordingly, the light utilization efficiency of the light-emitting array module 100 can be effectively improved.

Besides, since the light 113 does not become the stray light which may be projected into a neighboring microlens unit 200, the structural design of the light-emitting array module 100 in the present embodiment may effectively improve the impact of the stray light on the sharpness and the clarity of an image (such as a 3D image) produced by the microlens array, preventing blurred edges of the image pattern. Thus, the embodiment can enhance the imaging quality and suppress the unexpected color mixing of the image pattern. In other words, the light-emitting array module 100 provided in the present embodiment may effectively concentrate light and enhance the utilization efficiency of the light source, so as to obtain more useful light. The purified light hitting the corresponding position is able to improve the clarity, the sharpness, and/or the color saturation of the image, thereby enhancing the value of the product.

In the present embodiment, a refractive index of the microlens 210 and the refractive index of the stray light guiding layer 220 may, for instance, fall within a range from 1.1 to 6.0, preferably within a range from 1.0 to 5.0; the refractive index of the medium or the space on the outer side of the stray light guiding layer 220 may, for instance, fall within a range from 1.0 to 5.1, preferably within a range from 1.0 to 4.1.

In an embodiment, the combination of the stray light reflecting layer 230 and the stray light guiding layer 220 allows the light 113 (i.e., the stray light) emitted by the light-emitting elements 112 at a viewing angle of 65 degrees to 90 degrees, for instance, to be guided and converted to effective light and enables the light 113 to be transmitted to the refractive surface 212. Therefore, the light-emitting array module 100 of the present embodiment indeed achieves the better light utilization efficiency. The following table contains verification data obtained through optical simulation, where the refractive index of the microlens 210 is, for instance, 1.49, the refractive index of the stray light guiding layer 220 is, for instance, 1.59, and the refractive index of the medium (e.g., air) outside the stray light guiding layer 220 is set as 1, for instance.

| | | | | 4. Microlens + |
|---|---|---|---|---|
| | | | | stray light |
| | 1. No | 2. | 3. Microlens + | guiding layer + |
| | microlens | Microlens | stray light | stray light |
| Scenario (1-4) | unit | only | guiding layer | reflecting layer |
| Maximum | 694.54 | 1630.4 | 14148 | 55398 |
| radiance | | | | |
| (Watt/square | | | | |
| centimeter) | | | | |
| Comparison | 100.0% | 234.7% | 2037.0% | 7976.2% |
| (%) | | | | |

As shown in the table, in the scenario 1, a comparative example where the light source array 110 is provided but no microlens unit is adopted is provided; in the scenario 2, a comparative example where the light source array 110 and the microlens 210 are adopted is provided; in the scenario 3, a comparative example where the light source array 110, the microlens 210, and the stray light guiding layer 220 are adopted is provided; in the scenario 4, the light-emitting array module 100 disclosed in the present embodiment is provided. In addition, “Comparison (%)” refers to the percentage compared to the maximum radiance in the scenario 1. As can be seen from the above table, the maximum radiance of the light-emitting array module 100 (in the scenario 4) provided in the present embodiment is more than 30 times the maximum radiance of the light source array using the microlens (in the scenario 2), which proves that the light-emitting array module 100 provided in the present embodiment indeed effectively improves the light utilization efficiency.

In the present embodiment, the refractive index of the microlens 210 is less than the refractive index of the stray light guiding layer 220. Therefore, when the light 113 is incident on the surface 223 of the stray light guiding layer 220 at an incident angle greater than the critical angle, the surface 223 becomes a total internal reflection surface and totally reflects the light 113, thereby confining the light 113 within the stray light guiding layer 220. In the present embodiment, the edge of the microlens 210 may cover the other side 224 of the stray light guiding layer 220 away from the light source array 110. The light 113 entering the stray light guiding layer 220 from the one side 222 of the stray light guiding layer 220 is continuously totally reflected by the surfaces 221 and 223, and transmitted to the other side 224 of the stray light guiding layer 220. Then, the light 113 enters the edge of the microlens 210 from the other side 224 of the stray light guiding layer 220 and is refracted by the refractive surface 212 to form the effective light.

In the present embodiment, the refractive surface 212 of the microlens 210 faces away from the light source array 110, and the refractive surface 212 is a spherical surface, an aspherical surface, or a free-form surface. In an embodiment, the refractive surface 212 of the microlens 210 and the light source array 110 may collectively contribute to the formation of a light field image, which may be a 3D integral image. In the present embodiment, there are air gaps G1 between the stray light guiding layers 220 of the adjacent microlens units 200; that is, the medium on the outer side of the stray light guiding layers 220 is air, and the surfaces 221 of the stray light guiding layers 220 are interfaces between the stray light guiding layers 220 and the air.

In the present embodiment, each microlens unit 200 may further include a passivation layer 240 that covers the light source array 110 and is disposed between the microlens 210 and the light source array 110. The stray light reflecting layer 230 may be embedded into the passivation layer 240. The passivation layer 240 may be, for instance, an organic passivation layer or an inorganic passivation layer, and may achieve a planarization effect. In the present embodiment, the stray light reflecting layer 230 is disposed on at least one side of a carrier 242 (the side close to the light-emitting elements 112 and/or the microlens 210), where the shape, the size, and the material of the carrier 242 may be determined according to actual needs. The material of the carrier 242 may include an organic material, an inorganic material, or metal, and the carrier 242 may serve as a pixel definition layer (PDL) or a black matrix (BM). The stray light guiding layer 220 may be of a circular ring shape, and the top view of the stray light reflecting layer 230 may also be of a circular ring shape, as shown in FIG. 1B. However, in some embodiments, the stray light guiding layer 220 may be of a polygonal ring shape, and the top view of the stray light reflecting layer 230 may also be of a polygonal ring shape. In other embodiments, the top view of the stray light guiding layer 220 and the stray light reflecting layer 230 may also be of an irregular shape or a partially disconnected and not completely continuous shape.

In the present embodiment, the stray light reflecting layer 230 includes an inclined reflection portion 232, which is inclined relative to the light source array 110 and the stray light guiding layer 220. The inclined reflection portion 232 is configured to reflect the stray light (e.g. the light 113) emitted by the light-emitting elements 112 to the stray light guiding layer 220. In the present embodiment, the refractive surface 212 of the carrier 242 and/or microlens 210 may be formed by performing exposure, development, and etching processes using a grayscale photomask. In another embodiment, the stray light reflecting layer 230 may also replace the carrier 242 and may be manufactured by using a grayscale photomask with performing exposure, development, etching, and other processes.

In addition to serving as a display, the light-emitting array module 100 provided in the present embodiment may also act as a lighting device or may be applied to virtual reality, augmented reality, or mixed reality devices. Moreover, the arrangement of the red light-emitting element 112r, the green light-emitting element 112g, and the blue light-emitting element 112b may be determined according to the required arrangement manner of sub-pixels of various displays.

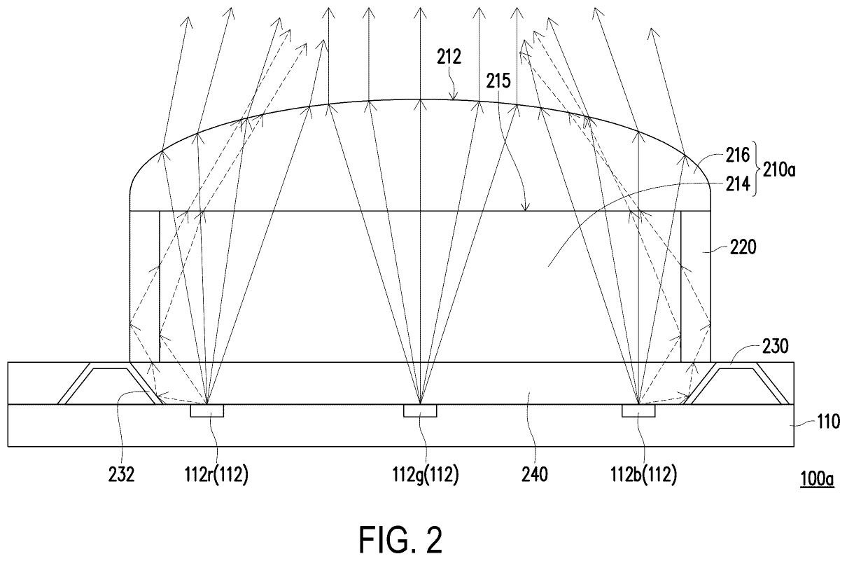

FIG. 2 is a schematic partial cross-sectional view of a light-emitting array module covering a microlens unit according to another embodiment of the disclosure. With reference to FIG. 2, a light-emitting array module 100a provided in the present embodiment may be partially similar to the light-emitting array module 100 in FIG. 1A. In the light-emitting array module 100a provided in the present embodiment, a microlens 210a includes a flat portion 214 and a lens portion 216. The flat portion 214 may be surrounded by the stray light guiding layer 220, and a refractive index of the flat portion 214 is less than the refractive index of the stray light guiding layer 220. The lens portion 216 is disposed on a surface 215 of the flat portion 214 facing away from the light source array 110. In addition, a refractive index of the lens portion 216 may be the same as or different from the refractive index of the flat portion 214.

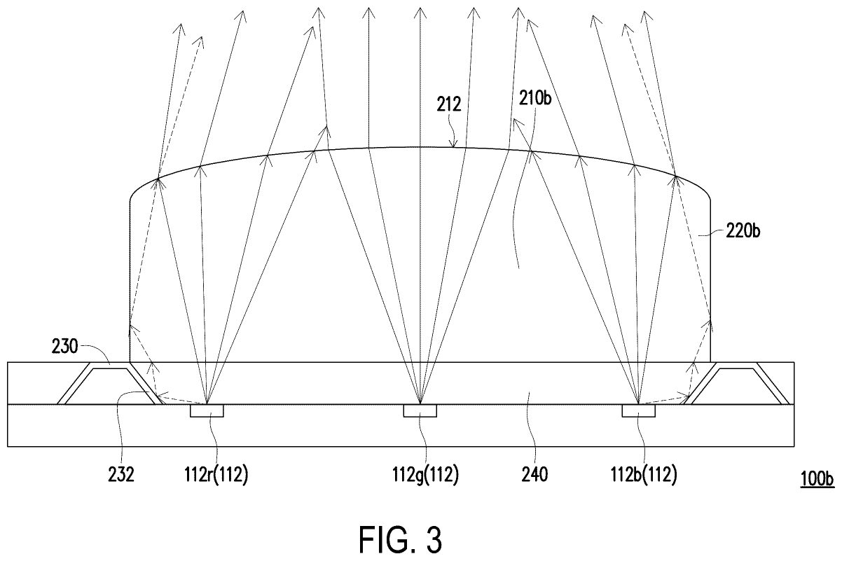

FIG. 3 is a schematic partial cross-sectional view of a light-emitting array module covering a microlens unit according to yet another embodiment of the disclosure. With reference to FIG. 3, a light-emitting array module 100b provided in the present embodiment may be partially similar to the light-emitting array module 100 in FIG. 1A. In the light-emitting array module 100b provided in the present embodiment, a microlens 210b and a stray light guiding layer 220b are integrally formed and made of the same material, and a refractive index of a medium or space on the outer side of the stray light guiding layer 220b is less than a refractive index of the stray light guiding layer 220b.

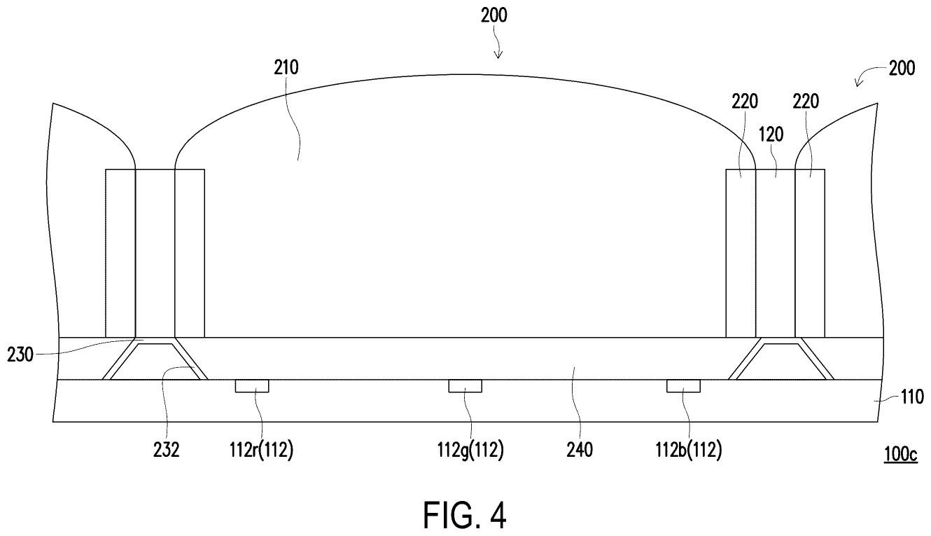

FIG. 4 is a schematic partial cross-sectional view of a light-emitting array module covering a microlens unit and a portion of surrounding microlens units according to still another embodiment of the disclosure. With reference to FIG. 4, a light-emitting array module 100c provided in the present embodiment may be partially similar to the light-emitting array module 100 in FIG. 1A. In the light-emitting array module 100c provided in the present embodiment, the stray light guiding layers of the adjacent microlens units 200 are connected by a connection portion 120, where a refractive index of the connection portion 120 may be less than the refractive index of the stray light guiding layers 220. In the light-emitting array module 100 in FIG. 1A, the connection portion 120 in FIG. 4 is replaced by the air gaps G1 (indicated in FIG. 1B).

In the light-emitting array module provided in one or more embodiments of the disclosure, the stray light guiding layer and the stray light reflecting layer are adopted, and the light emitted by the light-emitting elements corresponding to the microlens units and reflected into the stray light guiding layer by the stray light reflecting layer undergoes the total internal reflection on the surface of the stray light guiding layer. Therefore, the stray light reflecting layer and the stray light guiding layer are able to guide the stray light emitted by the light-emitting elements into the effective light, thereby enhancing the light utilization efficiency and/or improving the display performance.

It will be apparently addressed to those skilled in the art that various modifications and variations can be made to the structure of the disclosed embodiments without departing from the scope or spirit of the disclosure. In view of the foregoing, it is intended that the disclosure cover modifications and variations of the disclosure provided they fall within the scope of the following claims and their equivalents.

What is claimed is:

1. A light-emitting array module, comprising:
a light source array, comprising a plurality of light-emitting elements arranged in an array; and
a plurality of microlens units, disposed on the light source array, each of the microlens units comprising:
a microlens;
a stray light guiding layer, disposed on a side surface of the microlens, wherein a refractive index of a medium or space on an outer side of the stray light guiding layer is less than a refractive index of the stray light guiding layer; and
a stray light reflecting layer, disposed at one side of the stray light guiding layer adjacent to the light source array, wherein light emitted by the light-emitting elements corresponding to the microlens units and reflected into the stray light guiding layer by the stray light reflecting layer undergoes total internal reflection on a surface of the stray light guiding layer.

2. The light-emitting array module according to claim 1, wherein a refractive index of the microlens is less than the refractive index of the stray light guiding layer.

3. The light-emitting array module according to claim 1, wherein the stray light reflecting layer is disposed on a surface located on at least one side a carrier.

4. The light-emitting array module according to claim 1, wherein the stray light guiding layer, the stray light reflecting layer, or both are of a circular ring shape, a polygonal ring shape, an irregular shape, or a partially disconnected and not completely continuous shape.

5. The light-emitting array module according to claim 1, wherein the microlens has a refractive surface facing away from the light source array, and the refractive surface is a spherical surface, an aspherical surface, or a free-form surface.

6. The light-emitting array module according to claim 1, wherein air gaps exist between the stray light guiding layers of the adjacent microlens units.

7. The light-emitting array module according to claim 1, wherein the stray light guiding layers of the adjacent microlens units are connected by a connection portion, and a refractive index of the connection portion is less than the refractive index of the stray light guiding layers.

8. The light-emitting array module according to claim 1, wherein the microlens comprises:
a flat portion, surrounded by the stray light guiding layer, wherein a refractive index of the flat portion is less than the refractive index of the stray light guiding layer; and
a lens portion, disposed on a surface of the flat portion facing away from the light source array.

9. The light-emitting array module according to claim 1, wherein the microlens and the stray light guiding layer are integrally formed, and a material of the microlens is identical to a material of the stray light guiding layer.

10. The light-emitting array module according to claim 1, wherein each of the microlens units further comprises a passivation layer covering the light source array and disposed between the microlens and the light source array, and the stray light reflecting layer is embedded into the passivation layer.

11. The light-emitting array module according to claim 10, wherein the passivation layer is an organic passivation layer or an inorganic passivation layer.

12. The light-emitting array module according to claim 1, wherein the stray light reflecting layer comprises an inclined reflection portion inclined relative to the light source array and the stray light guiding layer, and the inclined reflection portion is configured to reflect stray light emitted by the light-emitting elements to the stray light guiding layer.

13. The light-emitting array module according to claim 1, wherein an edge of the microlens covers the other side of the stray light guiding layer away from the light source array.

14. The light-emitting array module according to claim 1, wherein the refractive index of the stray light guiding layer falls within a range from 1.1 to 6.0, a refractive index of the microlens falls within a range from 1.0 to 6.0, and the refractive index of the medium or the space on the outer side of the stray light guiding layer falls within a range from 1.0 to 5.1.
